(19) United States
(12) Patent Application Publication
(10) Pub. No.: US 2020/0037454 A1
(43) Pub. Date: Jan. 30, 2020

(54) PCB ELECTROLYTIC CAPACITOR RETAINER

(71) Applicant: Continental Automotive Systems, Inc., Auburn Hills, MI (US)

(72) Inventors: Lukasz Koczwara, Schaumburg, IL (US); Edward Hribar, Palos Hills, IL (US); Timothy J. Trento, Bloomingdale, IL (US); James D. Baer, Gurnee, IL (US)

(73) Assignee: Continental Automotive Systems, Inc., Auburn Hills, MI (US)

(21) Appl. No.: 16/045,233

(22) Filed: Jul. 25, 2018

(51) Int. Cl. H05K 3/30; H05K 7/08; H05K 7/12

(52) U.S. Cl. CPC H05K 3/301; H05K 2201/10606; H05K 7/12; H05K 7/08

(57) ABSTRACT

A retainer device which connects to a printed circuit board (PCB) to provide added structural rigidity to a capacitor (or other electrical component) mounted to the PCB. The retainer device is able to provide increased durability of capacitor leads against vibrational fatigue. The retainer device is designed to add structural rigidity to single or multiple capacitors soldered to a PCB. The retainer device exerts a positive force against the capacitor, pressing the capacitor against the PCB. This in turn limits the fatigue deflection of the capacitor leads. The retainer device has at least one spring retention ring, where the spring retention ring is able to apply force to the capacitor, which aids in ensuring that the capacitor is flush to the surface of the PCB, which reduces the load on the leads of the capacitor.

### FIELD OF THE INVENTION

The invention relates generally to a retainer device made from a one-piece stamped design, where the device is used for connecting electrical components, such as a capacitor, to a circuit board.

### BACKGROUND OF THE INVENTION

Electrolytic capacitors are typically used in motor control applications to achieve the high capacitance needed to prevent excessive supply voltage fluctuations when switching the output stages on and off. The electrolytic capacitor acts as a nearby charge reservoir, as opposed to the vehicle battery, which is connected via wire of substantial length. One concern with electrolytic capacitors (or other electrical components) is maintaining the capacitor in place when the capacitor is exposed to vibration, shock, or other harsh physical environments.

Many current capacitor clips do not have through-hole features to selectively solder the clip to a printed circuit board (PCB). Furthermore, these current capacitor clips do not add structural rigidity to capacitors mounted to a PCB, and also do not provide increased durability against vibrational fatigue.

Accordingly, there exists a need for a retention structure which stabilizes the capacitor during the manufacturing process, as well as prevents the capacitor from moving when being exposed to harsh environments.

### SUMMARY OF THE INVENTION

In one embodiment, the present invention is a retainer device which connects to a printed circuit board (PCB) to provide added structural rigidity to a capacitor (or other electrical component) also mounted to the PCB. The retainer device of the present invention is able to provide increased durability of capacitor leads exposed to vibrational fatigue.

The retainer device of the present invention is designed to add structural rigidity to single or multiple capacitors soldered to a PCB. The retainer device exerts a positive force against the capacitor, pressing the capacitor against the PCB. This in turn limits the fatigue deflection of the capacitor leads.

In one embodiment, the retainer device is a one-piece stamped design. The retainer device of the present invention has retainer leads, which are able to distribute the load needed to retain the capacitor in place away from the capacitor leads.

In one embodiment, the retainer device has at least one spring retention ring, where the spring retention ring is able to apply force to the capacitor, which aids in ensuring that the capacitor is flush to the surface of the PCB, which reduces the load on capacitor leads.

The force applied to the PCB is contained within the retainer device, such that the retainer device does not create an external force to surrounding features outside of the retainer, capacitor, and PCB assembly.

In one embodiment, the retainer device is selectively soldered to the PCB using the same process used to connect the capacitors to the PCB. However, in other embodiments, the retainer device includes press-fit pins which are inserted into corresponding vias of the PCB, providing a press-fit connection to the PCB.

In one embodiment, the present invention is an electronic component assembly, which includes at least one capacitor, a circuit board, and a retention device having a spring. The spring deflects and applies force to the capacitor to retain the capacitor in place when the retention device and the capacitor are attached to the circuit board. The retention device includes an outer frame portion, and the spring is connected to the outer frame portion. In one embodiment, the outer frame portion and the spring are concentric relative to one another. The retention device includes at least one connecting portion, and the spring is connected to the outer frame portion using the connecting portion.

In one embodiment, the retention device includes a plurality of stamped fingers integrally formed with the outer frame portion, and each of the plurality of stamped fingers is connected to the circuit board.

In one embodiment, the retention device has at least one wave portion formed as part of the spring. The wave portion deflects and applies force to the capacitor when the retention device is connected to the circuit board.

In one embodiment, the wave portion is in contact with, and applies force to, a back surface of the capacitor when the retainer device and the capacitor are connected to the circuit board.

In one embodiment, the capacitor is an axially mounted capacitor having a circumferential outer surface, and the wave portion is in contact with, and applies force to, the circumferential outer surface of the capacitor.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 is a perspective view of a capacitor assembly having a retainer device, according to embodiments of the present invention;

FIG. 2 is a perspective view of a retainer device used as part of a capacitor assembly, according to embodiments of the present invention;

FIG. 3 is an exploded view of a capacitor assembly having a retainer device, according to embodiments of the present invention; and

FIG. 4 is a perspective view of a second embodiment of a capacitor assembly having a retainer device, according to embodiments of the present invention.

### DETAILED DESCRIPTION OF THE PREFERRED EMBODIMENTS

The following description of the preferred embodiment(s) is merely exemplary in nature and is in no way intended to limit the invention, its application, or uses.

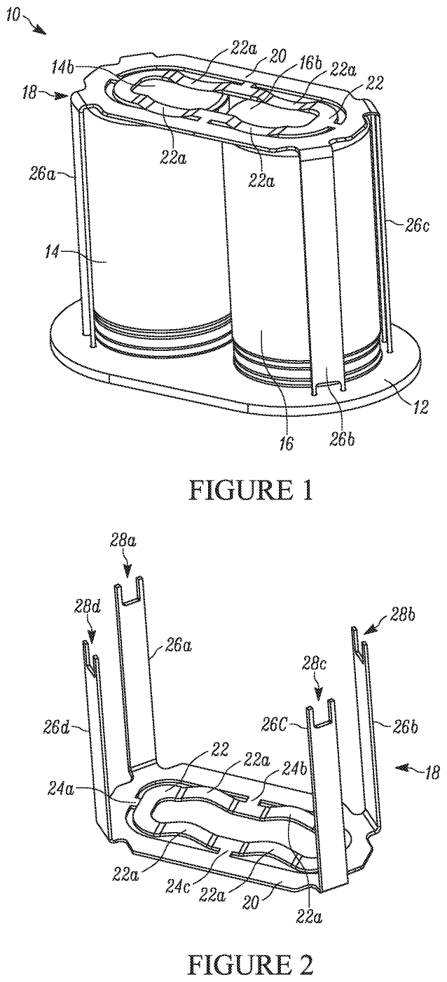

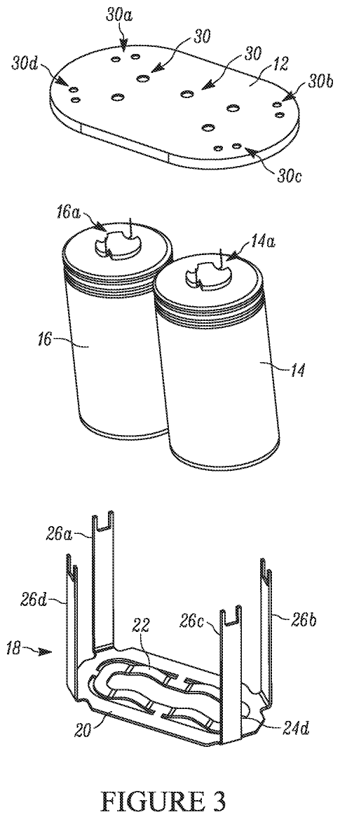

An electronic component assembly having a retainer device according to the present invention is shown in FIG. 1, generally at 10. In this embodiment, the electronic component assembly is a capacitor assembly 10 which includes a printed circuit board (PCB) 12, and connected to the PCB 12 is a first capacitor 14 and a second capacitor 16, both of which have leads shown at 14a,16a, respectively. While leads 14a,16a of both capacitors 14,16 are connected to the PCB 12, there is a retainer device, shown generally at 18, which is also connected to the PCB 12, and retains the capacitors 14,16 in place, and also applies a force to each capacitor 14,16.

More particularly, the retainer device 18 includes an outer frame portion, which in this embodiment is a spring retention ring 20, and the spring retention ring 20 substantially circumscribes a biasable member, which in this embodiment is a spring 22. The spring 22 in this embodiment is a wave spring 22, but it is within the scope of the invention that other types of springs may be used. The spring 22 is connected to the spring retention ring 20 using four connecting portions, shown at 24a,24b,24c,24d. The four connecting portions 24a,24b,24c,24d are spaced approximately ninety degrees apart, but it is within the scope of the invention that more or less connecting portions having different spacing may be used. The spring retention ring 20 and the spring 22 are substantially oval-shaped, and the spring retention ring 20 and the spring 22 are concentric relative to one another. However, it is within the scope of the invention that the spring retention ring 20 and the spring 22 may be different shapes, and may be arranged such that they are not concentric relative to one another.

Also integrally formed with the spring retention ring 20 is a plurality of attachment features, which in this embodiment is a plurality of stamped fingers 26a,26b,26c,26d. Each of the stamped fingers 26a,26b,26c,26d includes a corresponding pair of solder leads, shown generally at 28a,28b,28c,28d, which are used for connecting the retainer device 18 to the PCB 12.

The PCB 12 includes a plurality of conductive vias, shown generally at 30, which are operable for connection with the various leads 14a,16a of each capacitor 14,16 and the leads 28a,28b,28c,28d of the stamped fingers 26a,26b,26c,26d.

During assembly, the capacitors 14,16 and the retainer device 18 are placed into a machine used for assembly, such as a selective solder machine. The PCB 12 is then placed into the selective solder machine, and the capacitors 14,16 and retainer device are clamped against the PCB 12, such that the spring 22 applies force to the capacitors 14,16, the leads 14a,16a of each capacitor 14,16 extend into corresponding vias 30 of the PCB 12, and the solder leads 28a,28b,28c,28d of the stamped fingers 26a,26b,26c,26d extend into corresponding vias 30a,30b,30c,30d of the PCB 12. The leads 14a,16a are then soldered to connect the capacitors 14,16 to the PCB 12, and the solder leads 28a,28b,28c,28d are soldered to connect the retainer device 18 to the PCB 12.

When the capacitors 14,16 and retainer device are clamped against the PCB 12, the retainer device 18 is positioned as shown in FIG. 1, such that the spring 22 applies force to the capacitors 14,16. More specifically, the spring 22 has wave portions 22a, and the spring 22 is positioned such that the wave portions 22a deflect, and apply a force to the back surfaces 14b,16b of the capacitors 14,16.

The force applied to the back surfaces 14b,16b of the capacitors 14,16 by the wave portions 22a of the spring 22 retains the position of the capacitors 14,16 relative to the PCB 12, such that when the capacitors 14,16 are exposed to vibration, shock, or other harsh physical environments, the position of the capacitors 14,16 relative to the PCB 12 is maintained. Maintaining the position of the capacitors 14,16 relative to the PCB 12 ensures that the capacitors 14,16 are flush to the surface of the PCB 12, which distributes the load needed to retain the capacitors 14,16 in place such that the load is distributed away from the leads 14a,16a, reducing the load on the leads 14a,16a of the capacitors 14,16. This also reduces or eliminates the fatigue deflection of the leads 14a,16a.

The retainer device 18 is connected to the PCB 12 such that the retainer device 18 does not create an external force to surrounding features outside of the retainer 18, capacitors 14,16, and capacitor assembly 10. The retainer device 18 also adds structural rigidity to the capacitors 14,16 mounted to the PCB 12, and also provides increased durability against vibrational fatigue. The retainer device 18 is also able to stabilize the capacitors 14,16 during the manufacturing process, as well as prevent the capacitors 14,16 from moving out of position when being exposed to harsh environments.

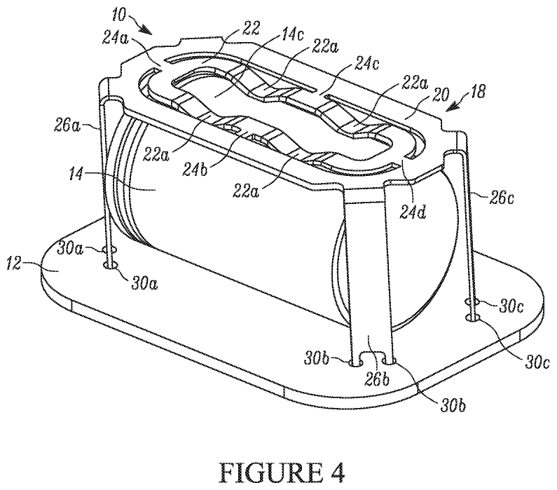

Another embodiment of the capacitor assembly 10 is shown in FIG. 4, with like numbers referring to like elements. In this embodiment, there is only one capacitor 14 shown, and the capacitor 14 is mounted axially, such that the spring 22, and more particularly the wave portions 22a are in contact with, and apply force to, a circumferential outer surface 14c. The solder leads 28a,28b,28c,28d are used to connect the retainer device 18 to the PCB 12 in the same manner as described above, and the force applied by the wave portion 22a retains the capacitor 14 in place, stabilizing the capacitor 14 during the manufacturing process, and reducing the loads on the leads 14a of the capacitor 14. The capacitor 14 may have the leads 14a extending from one end of the capacitor 14, or in other variations, there may be leads on each end of the capacitor 14.

While it has been shown in the Figures that four stamped fingers 26a,26b,26c,26d are integrally formed with the spring retention ring 20, it is within the scope of the invention that more or less stamped fingers 26a,26b,26c,26d may be used to provide distribute the load on the capacitors 14,16.

The description of the invention is merely exemplary in nature and, thus, variations that do not depart from the gist of the invention are intended to be within the scope of the invention. Such variations are not to be regarded as a departure from the spirit and scope of the invention.

1. A retainer device for an electronic component assembly, comprising:
an outer frame portion;
a spring integrally formed with the outer frame portion such that the outer frame portion substantially circumscribes the spring;
a plurality of stamped fingers integrally formed with the outer frame portion;
wherein the plurality of stamped fingers are connected to a circuit board, such that the spring applies a force to at least one capacitor, securing the capacitor to the circuit board.

2. The retainer device of claim 1, further comprising at least one connecting portion, the spring being connected to the outer frame portion using the at least one connecting portion.

3. The retainer device of claim 1, further comprising at least one wave portion formed as part of the spring.

4. The retainer device of claim 3, the at least one capacitor further comprising a back surface, wherein the at least one wave portion is in contact with the back surface of the at least one capacitor when the retainer device and the at least one capacitor are connected to the circuit board.

5. The retainer device of claim 4, wherein the at least one wave portion deflects and applies force to the back surface of the at least one capacitor when the retainer device and the at least one capacitor are connected to the circuit board.

6. The retainer device of claim 3, the at least one capacitor further comprising a circumferential outer surface, wherein the at least one capacitor is an axially mounted capacitor, and the at least one wave portion is in contact with the circumferential outer surface when the retainer device and the at least one capacitor are connected to the circuit board.

7. The retainer device of claim 6, wherein the at least one wave portion deflects and applies force to the circumferential outer surface when the retainer device and the at least one capacitor are connected to the circuit board.

8. The retainer device of claim 1, wherein the outer frame portion and the spring are concentric relative to one another.

9. An electronic component assembly, comprising:
at least one capacitor;
a circuit board;
a retainer device having an outer frame portion; and
a spring being part of the retainer device such that the outer frame portion is connected to and substantially circumscribes the spring;
wherein the spring deflects and applies force to the at least one capacitor to retain the at least one capacitor in place when the retention device and the at least one capacitor are attached to the circuit board.

10. (canceled)

11. The electronic component assembly of claim 9, wherein the outer frame portion and the spring are concentric relative to one another.

12. The electronic component assembly of claim 9, further comprising at least one connecting portion, the spring being connected to the outer frame portion using the at least one connecting portion.

13. The electronic component assembly of claim 9, the retainer device further comprising a plurality of stamped fingers integrally formed with the outer frame portion, wherein each of the plurality of stamped fingers is connected to the circuit board.

14. The electronic component assembly of claim 9, further comprising at least one wave portion formed as part of the spring, wherein the at least one wave portion deflects and applies force to the at least one capacitor when the retainer device is connected to the circuit board.

15. The electronic component assembly of claim 14, the at least one capacitor further comprising a back surface, wherein the at least one wave portion is in contact with, and applies force to, the back surface of the at least one capacitor when the retainer device and the at least one capacitor are connected to the circuit board.

16. The retainer device of claim 14, the at least one capacitor further comprising a circumferential outer surface, wherein the at least one capacitor is an axially mounted capacitor, and the at least one wave portion is in contact with, and applies force to, the circumferential outer surface of the at least one capacitor.
